(19) United States
(12) Patent Application Publication
(10) Pub. No.: US 2024/0194517 A1
(43) Pub. Date: Jun. 13, 2024

(54) SUBSTRATE PROCESSING APPARATUS

(71) Applicant: SEMES CO., LTD., Cheonan-si (KR)

(72) Inventors: Jaeoh BANG, Cheonan-si (KR); Jumi LEE, Cheonan-si (KR); Minyoung KIM, Cheonan-si (KR); Jong Gun LEE, Cheonan-si (KR)

(73) Assignee: SEMES CO., LTD., Cheonan-si (KR)

(21) Appl. No.: 18/515,638

(22) Filed: Nov. 21, 2023

(30) Foreign Application Priority Data
Dec. 9, 2022 (KR) 10-2022-0171660

(51) Int. Cl. H01L 21/687; G03F 7/40; H01L 21/67; H01L 21/683

(52) U.S. Cl. CPC H01L 21/6875; G03F 7/40; H01L 21/67109; H01L 21/6838; H01L 21/68742

(57) ABSTRACT

Disclosed is a substrate processing apparatus that allows a substrate to be supported on an ultra-thin heating plate so as to be spaced from the ultra-thin heating plate in a proximity manner. The substrate processing apparatus includes a heating plate for heating a substrate; and a through proximity pin installed in the heating plate so as to pass through a through-hole formed in the heating plate such that the substrate is spaced from the heating plate by a spacing via the through proximity pin.

### CROSS-REFERENCE TO RELATED PATENT APPLICATION

This application claims the benefit of Korean Patent Application No. 10-2022-0171660, filed on Dec. 9, 2022, in the Korean Intellectual Property Office, the disclosure of which is incorporated herein in its entirety by reference.

### BACKGROUND OF THE DISCLOSURE

### 1. Field of the Disclosure

The present disclosure relates to a substrate processing apparatus, and more specifically, to a substrate processing apparatus that allows a substrate to be supported on an ultra-thin heating plate so as to be spaced from the ultra-thin heating plate in a proximity manner.

### 2. Description of the Related Art

Generally, various processes such as cleaning, deposition, photolithography, etching, and ion implantation are performed to manufacture a semiconductor device. A photolithographic process is a process that forms a desired pattern on a substrate (wafer). The photolithographic process is usually carried out in a spinner local facility to which an exposure facility is connected and which sequentially performs a application process, an exposure process, and a developing process.

This spinner local facility sequentially or selectively performs a hydrophobization treating process, an application process, a baking process, and a developing process.

The hydrophobization treating process is a process that hydrophobizes the substrate by supplying a hydrophobization gas to the substrate before photoresist application to increase adhesion efficiency of the photoresist. The bake process is a process of heating and cooling the wafer to strengthen a photoresist film formed on the substrate or to adjust a temperature of the substrate to a preset temperature.

In this hydrophobization treating process or the baking process, a heating plate with a heater or heating wire pattern formed therein may be applied to quickly heat the substrate.

However, this existing heating plate is a component with a relatively high heat capacity to receive heat energy due to a large thickness thereof to have the heater built therein. However, due to the nature of the process that requires rapid repetition of heating and cooling, it take a very long time to heat the heating plate to a high temperature or cool the same to a low temperature.

In addition, in order to solve this existing problem, an attempt is being made to develop an ultra-thin heating plate. However, when the heating plate becomes thinner, an installation area of a partially inserted proximity pin partially inserted into a groove defined in an upper surface of the heating plate becomes very narrow, so that the installation thereof may become impossible due to a space limitation. In addition, when the groove is formed only on the upper surface of the ultra-thin heating plate, not only is manufacturing thereof cumbersome, but also stress is concentrated on a portion of the upper surface near the groove, which easily causes cracks to occur in the ultra-thin heating plate.

Further, there has been an attempt to form an integrated proximity protrusion on the upper surface of the ultra-thin heating plate. However, when the ultra-thin heating plate becomes thinner, it is difficult to form the proximity protrusion integrally with the ultra-thin heating plate due to the nature of the process, and cracks may occur due to an uneven load.

### SUMMARY OF THE DISCLOSURE

The present disclosure is intended to solve various problems, including the problems as described above. Thus, a purpose of the present disclosure is to provide a substrate processing apparatus in which a through proximity pin that may be conveniently installed into an ultra-thin heating plate may be used to overcome the limitation in reducing the thickness of the heating plate or the manufacturing limitation of the proximity pin.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means illustrated in the claims and combinations thereof.

According to a first aspect of the present disclosure, a substrate processing apparatus includes a heating plate for heating a substrate; and a through proximity pin installed in the heating plate so as to pass through a through-hole formed in the heating plate such that the substrate is spaced from the heating plate by a spacing via the through proximity pin.

In one implementation of the substrate processing apparatus, the through proximity pin includes: a head having a top, wherein a vertical level of the top is higher than a vertical level of an upper surface of the heating plate by the spacing so that the top is in contact with the substrate; a first fixed portion connected to the head and having a diameter larger than a diameter of the through-hole so that the first fixed portion and the head connected thereto is supported on the heating plate; and a waist connected to the first fixed portion and having a diameter smaller than or equal to the diameter of the through-hole such that the waist passes through the through-hole.

In one implementation of the substrate processing apparatus, the head has a spherical upper surface so as to be in point contact with the substrate.

In one implementation of the substrate processing apparatus, the first fixed portion is embodied as a flange contacting the upper surface of the heating plate.

In one implementation of the substrate processing apparatus, the first fixed portion is embodied as a flange inserted into a flange groove defined in the upper surface of the heating plate and extending from the through-hole.

In one implementation of the substrate processing apparatus, the flange includes: a flange body protruding outwardly from and extending around the head in a ring shape; and a grinding target portion including a lower surface of the flange body, wherein the grinding target portion is subjected to grinding so that the spacing can be selectively adjusted.

In one implementation of the substrate processing apparatus, the grinding target portion is embodied as a grinding target surface or at least one grinding target protrusion.

In one implementation of the substrate processing apparatus, the through proximity pin further includes a second fixed portion connected to the waist and fixed to the heating plate.

In one implementation of the substrate processing apparatus, the second fixed portion is embodied as a C-ring counterpart formed in a shape corresponding to a shape of a C-ring so that the waist is detachably fitted into the C-ring through an opening defined at one side thereof.

In one implementation of the substrate processing apparatus, the C-ring counterpart is embodied as a stepped portion having a diameter smaller than the diameter of the through-hole such that at least a portion thereof passes through the through-hole, and larger than the diameter of the waist such that the waist is fixed to the heating plate via the C-ring, wherein the C-ring includes one selected from a planar C-ring, an inclined C-ring, and an elastic spring coupled C-ring.

In one implementation of the substrate processing apparatus, the C-ring counterpart is embodied as a C-ring groove formed in the waist and in a shape corresponding to the shape of the C-ring so that the waist is fixed to the heating plate via the C-ring.

In one implementation of the substrate processing apparatus, the second fixed portion includes a fixing pin counterpart formed in the waist and in a shape corresponding to a fixing pin so that the fixing pin is detachably inserted into the fixing pin counterpart, wherein the fixing pin counterpart is embodied as a fixing pin receiving hole or groove.

In one implementation of the substrate processing apparatus, the second fixed portion is embodied as an elastically-deformable portion capable of elastic deformation so that the elastically-deformable portion is contracted when passing through the through-hole and is expanded after exiting the through-hole.

In one implementation of the substrate processing apparatus, the second fixed portion is embodied as a male threaded portion to which a fixing nut is screw-coupled.

In one implementation of the substrate processing apparatus, the through proximity pin further includes a handle connected to the second fixed portion, wherein the handle is gripped by a hand.

In one implementation of the substrate processing apparatus, the through proximity pin further includes a heat-dissipating portion connected to the second fixed portion and made of a heat dissipating material to dissipate heat transferred thereto from the head to an outside.

In one implementation of the substrate processing apparatus, the through proximity pin has a length larger than a thickness of the heating plate.

In one implementation of the substrate processing apparatus, the heating plate is embodied as an ultra-thin heating plate with a thickness of 2 mm or smaller, wherein the ultra-thin heating plate is used in a liquid film curing process of baking the substrate so as to dry a liquid film including a photo-resist film or an anti-reflection film applied onto the substrate, or in a substrate hydrophobization process of baking the substrate while supplying hexamethyldisilazane gas to increase adhesion of a photoresist.

According to a second aspect of the present disclosure, a substrate processing apparatus includes a housing having a treating space defined therein; and a support unit for supporting thereon a substrate received in the treating space, wherein the support unit includes: a heating plate having a heating wire pattern built therein to heat the substrate; a lift pin installed in the heating plate so as to vertically move the substrate; a guide member for aligning the substrate at a correct position; a vacuum hole defined in the heating plate so as to generate a vacuum pressure so that the substrate is adsorbed to the heating plate; and a through proximity pin installed in the heating plate so as to pass through a through-hole formed in the heating plate such that the substrate is spaced from the heating plate by a spacing via the through proximity pin.

According to a third aspect of the present disclosure, a substrate processing apparatus includes a heating plate having a heating wire pattern built therein to heat the substrate; and a through proximity pin installed in the heating plate so as to pass through a through-hole formed in the heating plate such that the substrate is spaced from the heating plate by a spacing via the through proximity pin, wherein the through proximity pin includes: a head having a top, wherein a vertical level of the top is higher than a vertical level of an upper surface of the heating plate by the spacing so that the top is in contact with the substrate; a first fixed portion connected to the head and having a diameter larger than a diameter of the through-hole so that the first fixed portion and the head connected thereto is supported on the heating plate; a waist connected to the first fixed portion and having a diameter smaller than or equal to the diameter of the through-hole such that the waist passes through the through-hole; and a second fixed portion connected to the waist and fixed to the heating plate, wherein the head has a spherical upper surface so as to be in point contact with the substrate, wherein the first fixed portion is embodied as a flange inserted into a flange groove defined in an upper surface of the heating plate and extending from the through-hole, wherein the flange includes a flange body protruding outwardly from and extending around the head in a ring shape; and a grinding target portion including a lower surface of the flange body, wherein the grinding target portion is subjected to grinding so that the spacing can be selectively adjusted, wherein the second fixed portion is embodied as a C-ring counterpart formed in a shape corresponding to a shape of a C-ring having an opening at one side thereof so that the C-ring counterpart is detachably fitted into the C-ring, wherein the C-ring counterpart is embodied as a stepped portion having the diameter smaller than the diameter of the through-hole such that at least a portion thereof passes through the through-hole, and larger than the diameter of the waist such that the waist is fixed to the heating plate via the C-ring, wherein the through proximity pin has a length larger than a thickness of the heating plate, wherein the heating plate is embodied as an ultra-thin heating plate with a thickness of 2 mm or smaller, wherein the ultra-thin heating plate is used in a liquid film curing process of baking the substrate so as to dry a liquid film including a photo-resist film or an anti-reflection film applied onto the substrate.

According to various embodiments of the present disclosure as described above, the through proximity pin that may be conveniently installed into the ultra-thin heating plate may be used to overcome the limitation in reducing the thickness of the heating plate or the manufacturing limitation of the proximity pin. Convenience in assembly may be maximized using the C-ring, the fixing pin, the elastically-deformable portion, the fixing nut, the handle, etc. The through-hole that extends vertically through the ultra-thin heating plate may be formed to eliminate the non-uniform stress concentration. The through proximity pin and the substrate may come into point contact with each other and a contact area between the through proximity pin and the inner wall of the heating plate defining the through-hole may be reduced to reduce thermal stress. Thermal shock to the substrate may be prevented by lowering the thermal conductivity of the head of the through proximity pin using an engineering plastic material such as PEEK or PEEK-CA with low thermal conductivity as the material of the head of the through proximity pin. The substrate may be heated quickly and uniformly by increasing heat dissipation using the through-hole or the heat-dissipating portion. A vertical level at which the substrate is supported may be controlled by grinding the grinding target portion.

Effects of the present disclosure are not limited to the effects mentioned above, and other effects not mentioned will be clearly understood by those skilled in the art from the descriptions below.

### BRIEF DESCRIPTION OF THE DRAWINGS

The above and other purposes, features and other advantages of the present disclosure will be more clearly understood from the following detailed description taken in conjunction with the accompanying drawings, in which:

FIG. 1 is a perspective view schematically showing a substrate processing apparatus according to some embodiments of the present disclosure;

FIG. 2 is a side elevation view showing the substrate processing apparatus in FIG. 1;

FIG. 3 is a top view of the substrate processing apparatus in FIG. 1;

FIG. 4 is a top view showing a hand of a transfer unit of the substrate processing apparatus in FIG. 3;

FIG. 5 is a top cross-sectional view schematically showing a heat-treatment chamber in FIG. 3;

FIG. 6 is a front cross-sectional view schematically showing the heat-treatment chamber in FIG. 3;

FIG. 7 is a front cross-sectional view of a heating unit in FIG. 6;

FIG. 8 is an enlarged cross-sectional view showing a through proximity pin of the heating unit in FIG. 7;

FIG. 9 is a perspective view showing an assembled state of the through proximity pin in FIG. 8;

FIG. 10 is an enlarged perspective view showing the through proximity pin and a C-ring of FIG. 9; and

FIGS. 11 to 18 are enlarged cross-sectional views showing several examples of through proximity pins according to various embodiments of the present disclosure.

### DETAILED DESCRIPTION OF THE DISCLOSURE

Hereinafter, various preferred embodiments of the present disclosure will be described in detail with reference to the attached drawings.

The embodiments of the present disclosure are provided to more completely describe the present disclosure for those skilled in the art. The following embodiments may be modified in various forms, and the scope of the present disclosure is not limited to the following embodiments. Rather, these embodiments are provided so that the present disclosure is thorough and complete, and are provided to fully convey the spirit of the present disclosure to those skilled in the art. Furthermore, a thickness or a size of each layer in the drawing is exaggerated for convenience and clarity of illustration. A shape, a size, a ratio, an angle, a number, etc. disclosed in the drawings for describing embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

Hereinafter, embodiments of the present disclosure will be described with reference to drawings schematically showing ideal embodiments of the present disclosure. In the drawings, variations of a depicted shape may be expected, depending, for example, on manufacturing techniques and/or tolerances. Therefore, the embodiments of the present disclosure should not be construed as being limited to the specific shape of the area shown herein, and should include, for example, change in a shape caused in a manufacturing process.

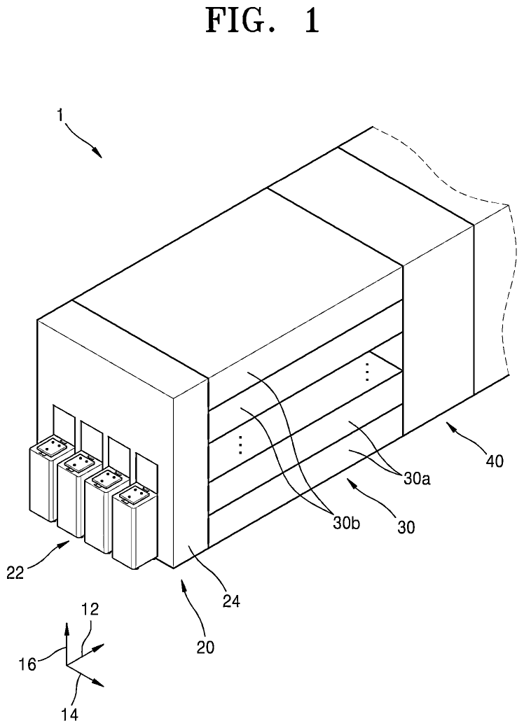

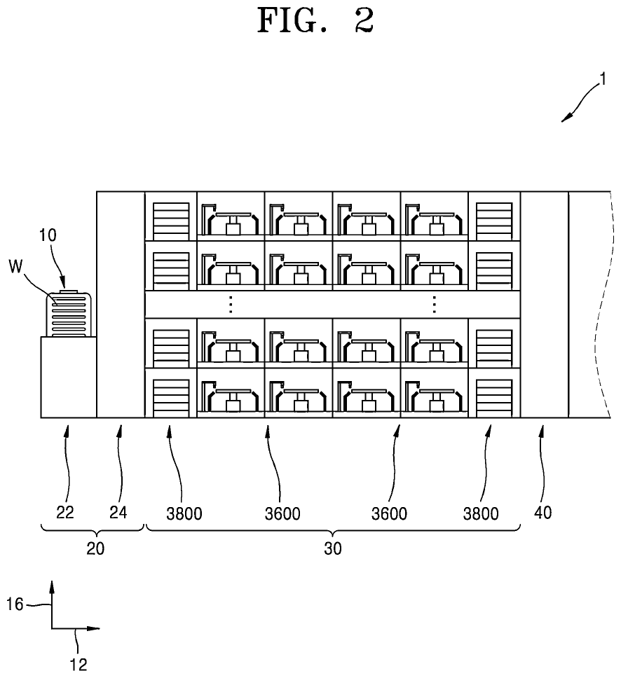

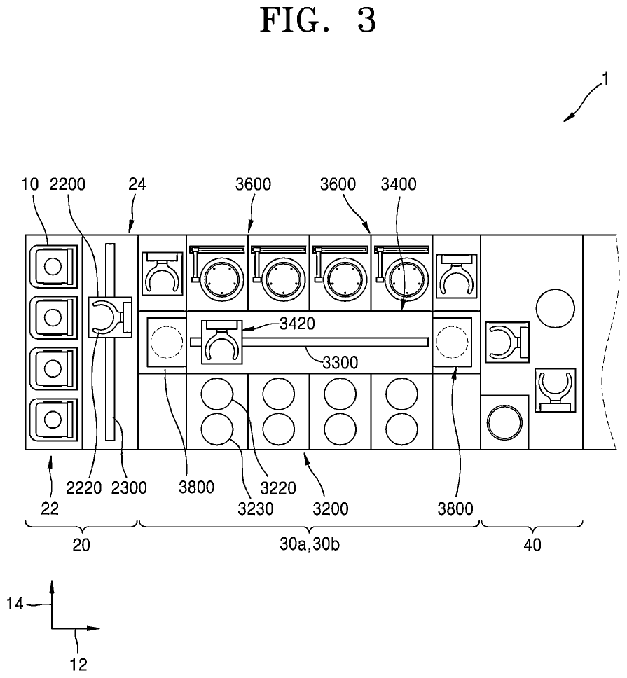

FIG. 1 is a perspective view schematically showing a substrate processing apparatus 1 according to some embodiments of the present disclosure, FIG. 2 is a side elevation view showing the substrate processing apparatus 1 in FIG. 1, and FIG. 3 is a top view showing the substrate processing apparatus 1 in FIG. 1.

As shown in FIGS. 1 to 3, the substrate processing apparatus 1 according to some embodiments of the present disclosure includes an index module 20, a treating module 30, and an interface module 40. According to one embodiment, the index module 20, the treating module 30, and the interface module 40 are sequentially arranged in a line. Hereinafter, a direction in which the index module 20, the treating module 30, and the interface module 40 are arranged is referred to as an X-axis direction 12, and a direction perpendicular to the X-axis direction 12 in a top view is a Y-axis direction 14. A Z-axis direction 16 is perpendicular to both the X-axis direction 12 and the Y-axis direction 14.

The index module 20 transfers the substrate W from a container 10 in which the substrate W is stored to the treating module 30, and stores a treated substrate W in the container 10. A length direction of the index module 20 is the Y-axis direction 14. The index module 20 has a load port 22 and an index frame 24. The load port 22 is opposite to the treating module 30 around the index frame 24. The container 10 containing the substrates W is disposed in the load port 22. A plurality of load ports 22 may be provided, and the plurality of load ports 22 may be arranged along the Y-axis direction 14.

The container 10 may be embodied as a sealed container 10 such as a front open unified pod (FOUP). The container 10 may be disposed in the load port 22 using transport means (not shown) such as an overhead transfer, an overhead conveyor, or an automatic guided vehicle (not shown) or by an operator.

An index robot 2200 is provided inside the index frame 24. Within the index frame 24, a guide rail 2300 extending in the Y-axis direction 14 as a length direction thereof is disposed. The index robot 2200 may be configured to be movable on the guide rail 2300. The index robot 2200 includes a hand 2220 on which the substrate W is placed.

The hand 2220 may be configured to move forward and backward, to rotate about the Z-axis direction 16, and to be movable in the Z-axis direction 16.

The treating module 30 performs an application process and a developing process on the substrate W. The treating module 30 has an application block 30a and a developing block 30b. The application block 30a performs the application process on the substrate W, and the developing block 30b performs the developing process on the substrate W. A plurality of application blocks 30a are provided, and are stacked on top of each other. A plurality of developing blocks 30b are provided, and the developing blocks 30b are stacked on top of each other. According to an embodiment of FIG. 1, two application blocks 30a are provided, and two developing blocks 30b are provided. The application blocks 30a may be disposed under the developing blocks 30b. In one example, the two application blocks 30a may perform the same process and may have the same structure. Furthermore, the two developing blocks 30b may perform the same process and may have the same structure. However, the present disclosure is not limited thereto.

Referring to FIG. 3, the application block 30a has a heat-treatment chamber 3200, a transfer chamber 3400, a liquid treatment chamber 3600, and a buffer chamber 3800. The heat-treatment chamber 3200 performs a heat-treatment process on the substrate W. The heat-treatment process may include a cooling process and a heating process. The liquid treating chamber 3600 supplies liquid on the substrate W to form a liquid film. The liquid film may be a photoresist film or an antireflection film. The transfer chamber 3400 transfers the substrate W to between the heat-treatment chamber 3200 and the liquid treatment chamber 3600 and within the application block 30a.

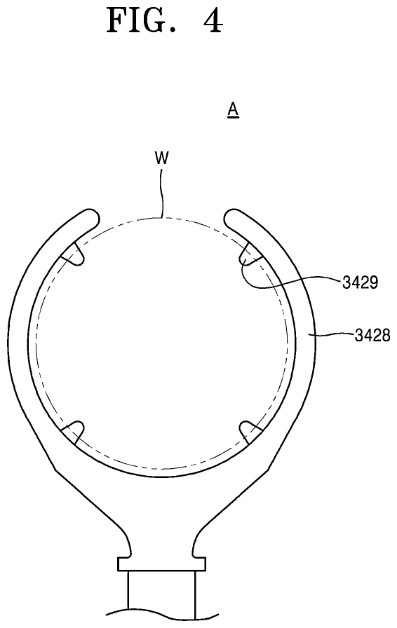

The transfer chamber 3400 has a length direction parallel to the X-axis direction 12. A transfer unit 3420 is provided in the transfer chamber 3400. The transfer unit 3420 transfers the substrate W to between the heat-treatment chamber 3200, the liquid treating chamber 3600, and the buffer chamber 3800. In one example, the transfer unit 3420 has a hand A (see FIG. 4) on which the substrate W is placed, wherein the hand A may be configured to move forward and backward, rotate about the Z-axis direction 16, and be movable along the Z-axis direction 16. A guide rail 3300 whose a length direction is parallel to the X-axis direction 12 is disposed in the transfer chamber 3400. The transfer unit 3420 may be configured to be movable on the guide rail 3300.

FIG. 4 is a plan view showing the hand A of the transfer unit 3420 of the substrate processing apparatus 1 in FIG. 3.

As shown in FIG. 4, the hand A has a base 3428 and a support protrusion 3429. The base 3428 may have an annular ring shape partially cut. The base 3428 has an inner diameter larger than a diameter of the substrate W. The support protrusion 3429 extends inwardly from the base 3428.

A plurality of support protrusions 3429 are provided to support an edge area of the substrate W. In an example, four support protrusions 3429 may be arranged by an equal spacing.

Referring again to FIG. 2 and FIG. 3, a plurality of heat-treatment chambers 3200 are provided. The heat-treatment chambers 3200 are arranged in a row along the X-axis direction 12. The heat-treatment chambers 3200 are located on one side of the transfer chamber 3400.

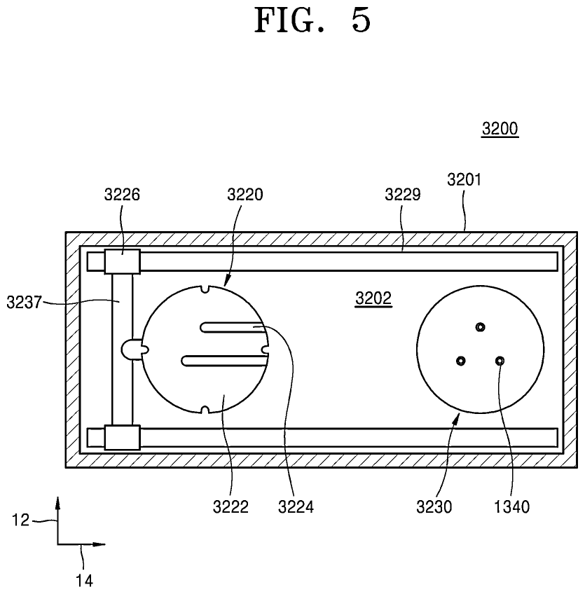

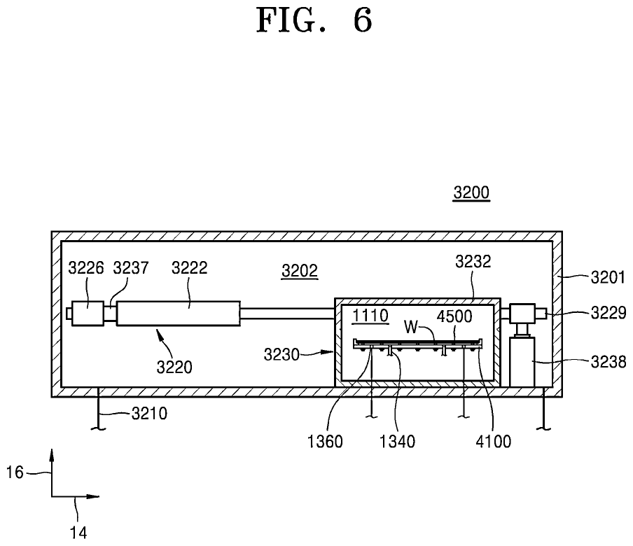

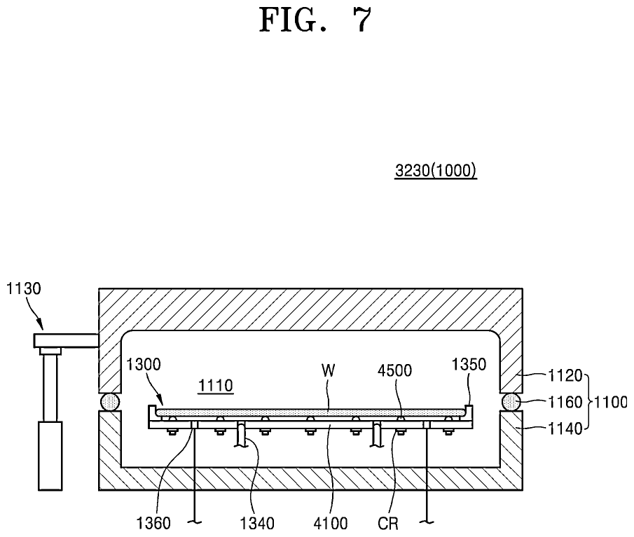

FIG. 5 is a top cross-sectional view schematically showing the heat-treatment chamber 3200 in FIG. 3. FIG. 6 is a front cross-sectional view schematically showing the heat-treatment chamber 3200 in FIG. 3. FIG. 7 is a front cross-sectional view of a heating unit 3230 in FIG. 6.

The heat-treatment chamber 3200 includes a treating container 3201, a cooling unit 3220, and the heating unit 3230.

The treating container 3201 has an internal space 3202. The treating container 3201 is generally formed in a shape of a rectangular parallelepiped. An inlet (not shown) through which the substrate W enters and exits is formed in a sidewall of the treating container 3201. Furthermore, a door (not shown) may be configured to open and close the inlet. The inlet may selectively be kept open. The inlet may be formed in an area adjacent to the cooling unit 3220. The cooling unit 3220 and the heating unit 3230 are disposed in the internal space 3202 of the treating container 3201. The cooling unit 3220 and the heating unit 3230 are arranged side by side along the Y-axis direction 14. An exhaust line 3210 may be connected to the treating container 3201. The exhaust line 3210 may exhaust gas supplied under an operation of a fan unit (not illustrated) out of the treating container 3201. The exhaust line 3210 may be connected to a bottom of the treating container 3201. However, the present is not limited thereto, and the exhaust line 3210 may be connected to a side, etc. of the treating container 3201.

The cooling unit 3220 has a cooling plate 3222. The substrate W may be disposed on the cooling plate 3222. The cooling plate 3222 may have a generally circular shape in a top view. A cooling member (not shown) is provided in the cooling plate 3222. In one example, the cooling member is formed inside the cooling plate 3222 and may be embodied as a flow path through which a cooling fluid flows. Accordingly, the cooling plate 3222 may cool the substrate W. The cooling plate 3222 may have a diameter corresponding to that of the substrate W. A notch may be formed at an edge of the cooling plate 3222. The notch may have a shape corresponding to that of the support protrusion 3429 formed on the hand A as described above. Furthermore, the number of notches may correspond to the number of the support protrusions 3429 formed on the hand A. Each notch may be positioned at a location corresponding to that of each of the support protrusions 3429. When a vertical level of each of the hand A and the cooling plate 3222 changes, the substrate W is transferred to between the hand A and the cooling plate 3222.

The cooling plate 3222 has a plurality of slit-shaped guide grooves 3224 defined therein. The guide groove 3224 extends from an end of the cooling plate 3222 to an inside of the cooling plate 3222. The guide groove 3224 has a length direction along the Y-axis direction 14. The guide grooves 3224 are arranged so as to be spaced apart from each other along the X-axis direction 12. The guide groove 3224 prevents the cooling plate 3222 and a lift pin 1340 from interfering with each other when the substrate is transferred to between the cooling plate 3222 and the heating unit 3230.

The cooling plate 3222 may be supported on a support member 3237. The support member 3237 may include a bar-shaped first support member and a second support member coupled to a middle of the first support member. One end and the other end of the first support member are coupled to a driver 3226. The driver 3226 is mounted on the guide rail 3229. In a top view, the guide rail 3229 has a length direction along the Y-axis direction 14 and may be provided on each of both opposing sides of the treating container 3201. The cooling plate 3222 may be movable along the Y-axis direction 14 under an operation of the driver 3226 mounted on the guide rail 3229.

The heating unit 3230 may include a housing 3232, a heating plate 4100, the lift pin 1340, and a driving member 3238. The housing 3232 may include a body and a cover. The body may be disposed at a bottom of the cover. The body may have an open top. The body may have a cylindrical shape with an open top. The cover may cover the open top of the body. The cover may have a cylindrical shape with an open bottom. Alternatively, the cover may have a plate shape that covers the top of the body. The body and the cover may be coupled to each other to form a treating space 1110. Furthermore, the cover may be connected to the driving member 3238 that moves the cover in an up or down direction. Accordingly, the cover may move in the up or down direction to open and close the treating space 1110. For example, when the substrate W enters or exits the treating space 1110, the cover may move upwardly to open the treating space 1110. Furthermore, when the substrate W is treated in the treating space 1110, the cover may move downwardly to close the treating space 1110.

The heating plate 4100 may support the substrate W in the treating space 1110. The substrate W may be disposed on the heating plate 4100. The heating plate 4100 has a generally circular shape in a top view. The heating plate 4100 has a larger diameter than that of the substrate W.

The heating plate 4100 may be embodied as an ultra-thin heating plate with a built-in heating wire pattern (not shown). The heating wire pattern is a type of a heater and may be embodied as a heating resistor that generates the heat when an electric current is applied thereto. Accordingly, the heating plate 4100 may heat the substrate W. The heating plate 4100 is provided with lift pins 1340 that may be movable upwardly or downwardly along the Z-axis direction 16. The lift pin 1340 receives the substrate W from transfer means outside the heating unit 3230 and places the same on the heating plate 4100 or lifts the substrate W from the heating plate 4100 and hands over the same the transfer means outside the heating unit 3230. In one example, three lift pins 1340 may be provided.

The heating unit 3230 includes a housing 1100 and a support unit 1300.

The housing 1100 has the treating space 1110 defined therein for heating the substrate W. The treating space 1110 is provided as a space sealed from an outside. The housing 1100 includes an upper body 1120, a lower body 1140, and a sealing member 1160.

The upper body 1120 is provided in a cylindrical shape with an open bottom. The lower body 1140 is provided in a shape of a cylinder with an open top. The lower body 1140 is located under the upper body 1120. The upper body 1120 and the lower body 1140 are positioned to face each other in the vertical direction. The upper body 1120 and the lower body 1140 are combined with each other to form the treating space 1110. The upper body 1120 and the lower body 1140 are positioned so that their central axes coincide with each other in the vertical direction.

The lower body 1140 may have the same diameter as that of the upper body 1120. That is, the top of the lower body 1140 may face the bottom of the upper body 1120.

One of the upper body 1120 and the lower body 1140 may be movable to an open position and a sealing position under an operation of the vertically-moving member 1130, and the other thereof is fixed in its position. In this embodiment, an example in which the position of the lower body 1140 is fixed and the upper body 1120 is movable is described. The open position is a position where the upper body 1120 and the lower body 1140 are spaced apart from each other such that the treating space 1110 is opened. The sealing position is a position where the treating space 1110 is sealed by the lower body 1140 and the upper body 1120 from the outside.

The sealing member 1160 is located between the upper body 1120 and the lower body 1140. The sealing member 1160 ensures that the treating space 1110 is sealed from the outside when the upper body 1120 and the lower body 1140 come into contact with each other. The sealing member 1160 may be provided in an annular ring shape. The sealing member 1160 may be fixedly coupled to the top of the lower body 1140.

The support unit 1300 supports the substrate W in the treating space 1110. The support unit 1300 includes a heating plate 4100 and a through proximity pin 4500.

The heating plate 4100 may have a generally circular shape in a top view. A vacuum hole 1360 connected to a vacuum line may be formed in the heating plate 4100.

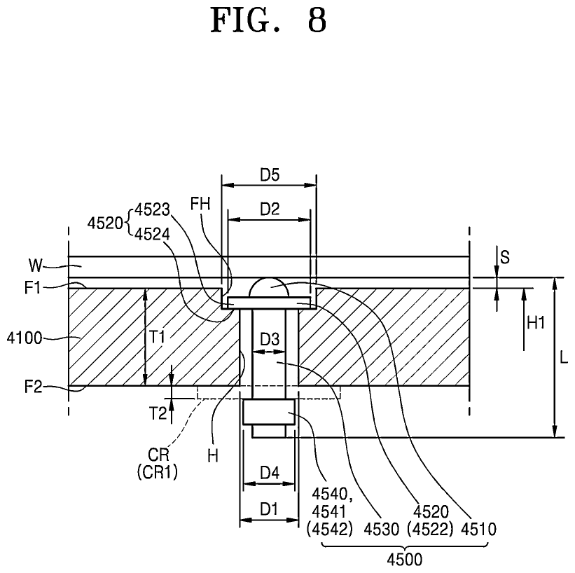

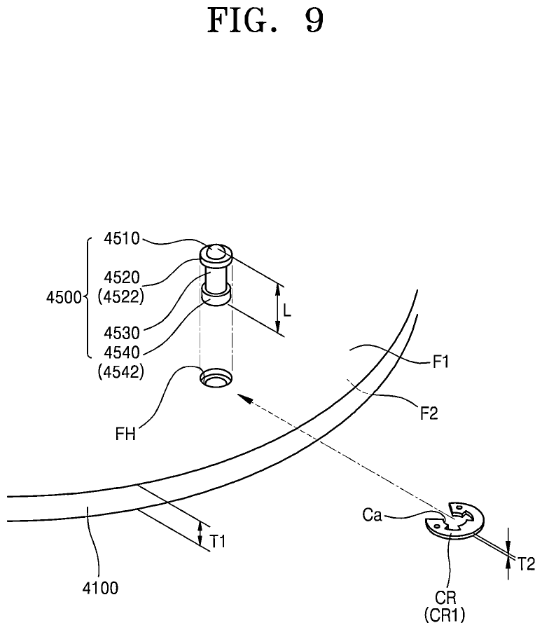

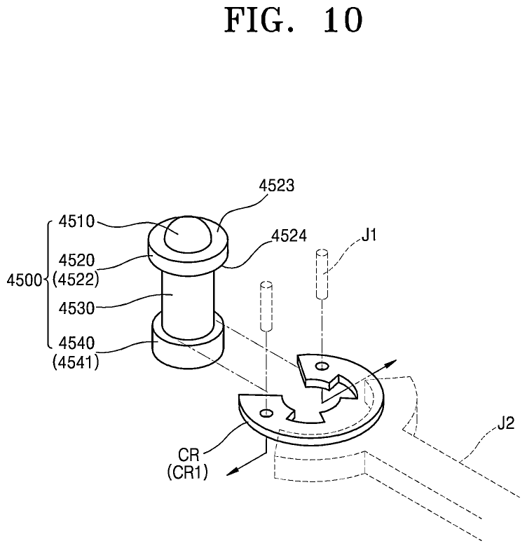

FIG. 8 is an enlarged cross-sectional view showing the through proximity pin 4500 of the heating unit 3230 in FIG. 7. FIG. 9 is a perspective view showing an assembled state of the through proximity pin 4500 in FIG. 8, and FIG. 10 is an enlarged perspective view showing the through proximity pin 4500 and a C-ring CR in FIG. 9.

As shown in FIGS. 8 to 10, a heating wire pattern (not shown) is formed inside the substrate processing apparatus 1 according to some embodiments of the present disclosure. The substrate processing apparatus 1 may include the heating plate 4100 which heats the substrate W and the through proximity pin 4500 which passes through a through-hole H formed in the heating plate 4100 and is installed in the heating plate 4100 so that the substrate W may be spaced apart from the heating plate 4100 by a spacing S.

In this regard, the through proximity pin 4500 may be formed to have a length L larger than a thickness T1 of the heating plate 4100 so as to pass through the heating plate 4100.

This heating plate 4100 may be embodied as an ultra-thin heating plate with a thickness of 2 mm or smaller which may be applied to a liquid film curing process of baking the substrate W so as to dry the liquid film such as a photo-resist (PR) film or an anti-reflection film applied to the substrate W, or may be applied to a substrate hydrophobization process of baking the substrate while supplying hexamethyldisilazane (HMDS) gas to increase the adhesion efficiency of the photoresist.

The through proximity pin 4500 may largely include a head 4510, a first fixed portion 4520, a waist 4530, and a second fixed portion 4540.

A vertical level of a top of the head 4510 is higher than that of an upper surface F1 of the heating plate 4100 having a height H1 by a spacing S, so that the top thereof is in contact with the substrate W. The head 4510 has a hemispherical shape or a dome-shape such that the head is in point contact with the substrate W. However, the shape of the head 4510 is not necessarily limited to the hemispherical or dome shape and may be formed in a variety of shapes, such as a pointed shape or a polyhedral shape whose a width is increasing smaller as the shape extends upwards.

Accordingly, the head 4510 may point-contact a back surface of the substrate W to minimize heat transfer, thereby minimizing thermal stress or thermal shock applied to the substrate W.

In this regard, the head 4510 may be made of a PEEK or PEEK-CA or a synthetic resin material such as Teflon or other engineering plastics as a material with thermal conductivity smaller than 1 W/mk in order to prevent local heat transfer that may occur at a contact area thereof with the substrate W. The head 4510 may be formed via injection molding or cutting of the PEEK or PEEK-CA or a synthetic resin material such as Teflon or other engineering plastics.

The first fixed portion 4520 may be integrally formed with the head 4510 and made of the same material as that of the head 4510. The first fixed portion 4520 and the head 4510 may be integrally formed with each other via injection molding. The first fixed portion 4520 may be embodied as a protruding portion having a diameter D2 greater than or equal to an inner diameter D1 of the through-hole H such that the head 4510 integrally formed therewith may be supported on a shoulder of the through-hole H of the heating plate 4100.

The first fixed portion 4520 may be embodied as a flange 4522 having a smaller diameter D2 than an inner diameter D5 of a flange groove FH defined in the upper surface F1 of the heating plate 4100 and extending upwardly from the through-hole H such that the flange 4522 may be inserted into the flange groove FH.

The flange 4522 may include a flange body 4523 extending beyond the head 4510 and having a ring shape, and a grinding target portion 4524 including a lower surface of the flange body 4523, wherein the grinding target portion 4524 may be ground such that the spacing S may be selectively adjusted.

The grinding target portion 4524 is a portion that may be ground using a grinding tool, and may be a grinding target surface or may be embodied as at least one grinding target protrusion (not shown) protruding downwardly from the flange body 4523 which can be easily ground.

The waist 4530 may be integrally formed with the first fixed portion 4520 and made of the same material as that of the first fixed portion 4520. The waist 4530 and the first fixed portion 4520 may be integrally formed with each other via injection-molding. The waist 4530 may have a diameter D3 that is smaller than or equal to the inner diameter D1 of the through-hole H so that the waist may pass through the through-hole H.

The waist 4530 may pass through the through-hole H and may be spaced apart from an inner wall of the heating plate 4100 defining the through-hole H so that the waist may be loosely inserted into the through-hole H to minimize heat energy transferred thereto from the heating plate 4100. However, the waist 4530 is not necessarily limited to what is illustrated in the drawing, and may also be in close contact with the inner wall of the heating plate 4100 defining the through-hole H and may forcibly fit into the through-hole H of the heating plate 4100.

The second fixed portion 4540 may be integrally formed with the waist 4530 and may be made of the same material as that of the waist 4530. The second fixed portion 4540 and the waist 4530 may be integrally formed with each other via injection-molding. The second fixed portion 4540 may be fixed to a lower surface F2 of the heating plate 4100.

The second fixed portion 4540 may act as a C-ring counterpart 4541 formed in a shape corresponding to that of the C-ring CR so that the C-ring counterpart 4541 may be detachably fitted into the C-ring CR having an opening Ca at one side.

The C-ring counterpart 4541 may be embodied as a stepped portion 4542 which may have a diameter D4 smaller than the inner diameter D1 of the through-hole H so that the stepped portion 4542 may pass through the through-hole H, and larger than the diameter D3 of the waist so that the waist 4530 can be fixed to the heating plate 4100 via the C-ring CR, for example, a planar C-ring CR1 formed in a general flat shape. The stepped portion 4542 may be spaced apart from the lower surface F2 of the heating plate 4100 by a spacing equal to or larger than a thickness T2 of the C-ring CR.

Therefore, according to the present disclosure, as shown in FIG. 9, the waist 4530 and the second fixed portion 4540 of the through proximity pin 4500 may pass through the through-hole H of the heating plate 4100, and the flange 4522 as the first fixed portion 4520 may be inserted into the flange groove FH such that an upper portion of the through proximity pin 4500 may be firmly fixed. Further, as shown in FIG. 10, the planar C-ring CR1 may be engaged with the stepped portion 4542 as the second fixed portion 4540 exposed to the outside after the waist 4530 and the second fixed portion 4540 of the through proximity pin 4500 have passed through the through-hole H of the heating plate 4100, such that a lower portion of the through proximity pin 4500 may be firmly fixed.

At this time, the opening Ca of the C-ring CR may be forcibly widened using a first jig J1 inserted into a jig hole formed therein and near the opening Ca. The C-ring CR may be easily inserted into a gap between the heating plate 4100 and the stepped portion 4542 using a second jig J2 which has a temporary mounting groove defined therein receiving the C-ring so that the C-ring may be forcibly fitted with the waist 4530.

This C-ring CR is not necessarily limited to what is illustrated in the drawing, may be embodied as various forms of C-rings or fixtures.

Therefore, the through proximity pin 4500 that may be conveniently installed into the ultra-thin heating plate 4100 may be used to overcome the limitation in reducing the thickness of the heating plate 4100 or the manufacturing limitation of the proximity pin.

Convenience in assembly may be maximized using the C-ring CR. The through-hole H that extends vertically through the ultra-thin heating plate 4100 may be formed to eliminate the non-uniform stress concentration. The through proximity pin 4500 and the substrate W may come into point contact with each other and a contact area between the through proximity pin 4500 and the inner wall of the heating plate 4100 defining the through-hole H may be reduced to reduce thermal stress. Thermal shock to the substrate W may be prevented by lowering the thermal conductivity of the head 4510 of the through proximity pin 4500 using an engineering plastic material such as PEEK or PEEK-CA with low thermal conductivity as the material of the head of the through proximity pin. The substrate W may be heated quickly and uniformly by increasing heat dissipation using the through-hole H. A vertical level at which the substrate W is supported may be controlled by grinding the grinding target portion 4524.

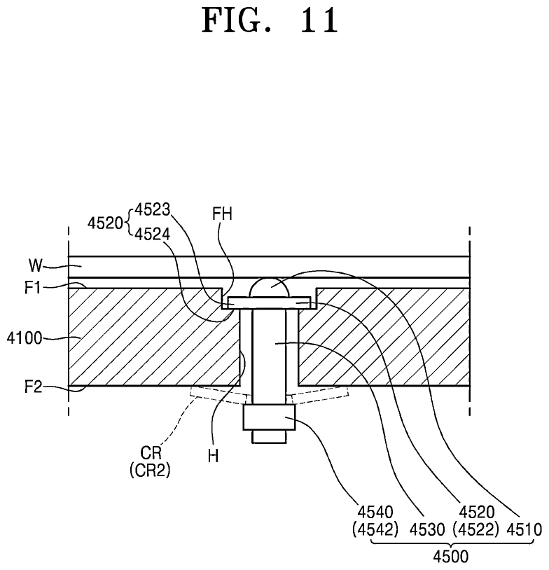

FIGS. 11 to 18 are enlarged cross-sectional views showing several examples of the through proximity pin 4500 according to various embodiments of the present disclosure.

As shown in FIG. 11, the second fixed portion 4540 of the through proximity pin 4500 according to some further embodiments of the present disclosure is embodied as the stepped portion 4542 which may be elastically fixed to the heating plate 4100 via an inclined C-ring CR2 having an elastic restoring force acting in up and down directions.

Therefore, even when thermal deformation of the heating plate 4100 or the through proximity pin 4500 occurs due to thermal expansion or thermal contraction, the elastic restoring force of the inclined C-ring CR2 may buffer the thermal deformation such that the stepped portion 4542 and the C-ring CR may always in elastically close contact with each other.

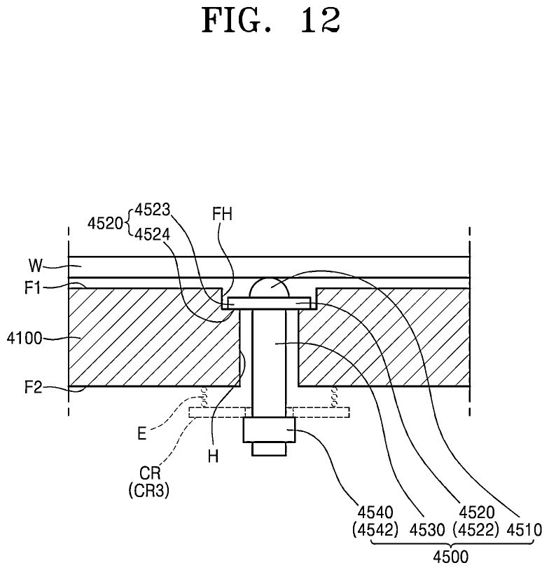

As shown in FIG. 12, the second fixed portion 4540 of the through proximity pin 4500 according to some further embodiments of the present disclosure is embodied as the stepped portion 4542 which may be elastically fixed to the heating plate 4100 via an elastic spring E coupled C-ring CR3 having an elastic restoring force acting in up and down directions.

Therefore, even when thermal deformation of the heating plate 4100 or the through proximity pin 4500 occurs due to thermal expansion or thermal contraction, the elastic restoring force of the elastic spring E coupled C-ring CR3 may buffer the thermal deformation such that the stepped portion 4542 and the C-ring CR may always in elastically close contact with each other.

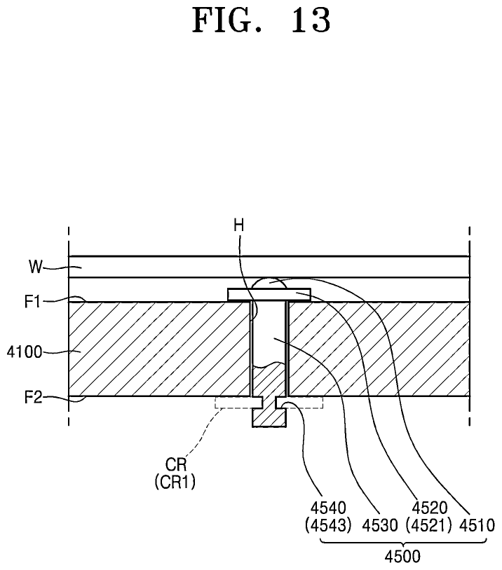

As shown in FIG. 13, in the through proximity pin 4500 according to some still further embodiments of the present disclosure, the first fixed portion 4520 may be embodied as a flange 4521 in contact with the upper surface F1 of the heating plate 4100, the waist 4530 may pass through the through-hole H and may be in close contact with the inner wall defining the through-hole H, and the second fixed portion 4540 may be embodied as a C-ring groove 4543 formed in the waist 4530 and in a shape corresponding to a C-ring CR so that the waist 4530 may be fixed to the heating plate 4100 via the C-ring CR.

Therefore, while there is no need to form the above-described flange groove FH in the upper surface F1 of the heating plate 4100, and there is no need to form the above-described stepped portion 4542 on the through proximity pin 4500, the waist 4530 may be inserted very simply into the through-hole H to firmly fix the top and the bottom of the through proximity pin 4500 to the heating plate 4100.

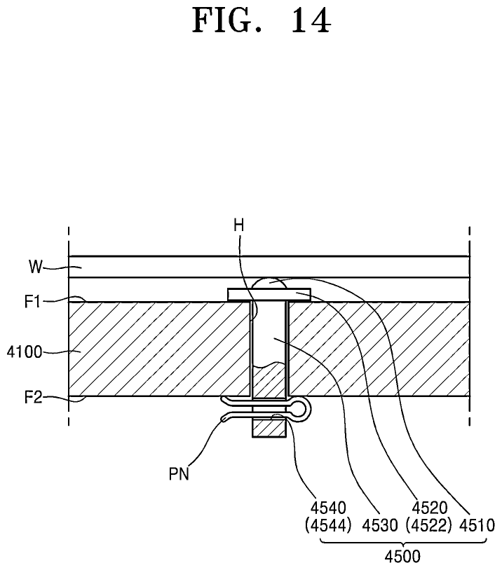

As shown in FIG. 14, in the through proximity pin 4500 according to some still further embodiments of the present disclosure, the second fixed portion 4540 may be embodied as a fixing pin counterpart 4544 (a pin receiving hole) formed in the waist and in a shape corresponding to a fixing pin PN such that the fixing pin PN instead of the above-described C-ring CR may be detachably inserted into the fixing pin counterpart 4544 (the pin receiving hole). In this regard, a pin receiving groove (not shown) formed in an outer surface of the waist may be formed as the fixing pin counterpart 4544 instead of the pin receiving hole.

Therefore, the operator may firmly fix the lower portion of the through proximity pin 4500 to the heating plate 4100 using the fixing pin PN instead of the above-described C-ring CR.

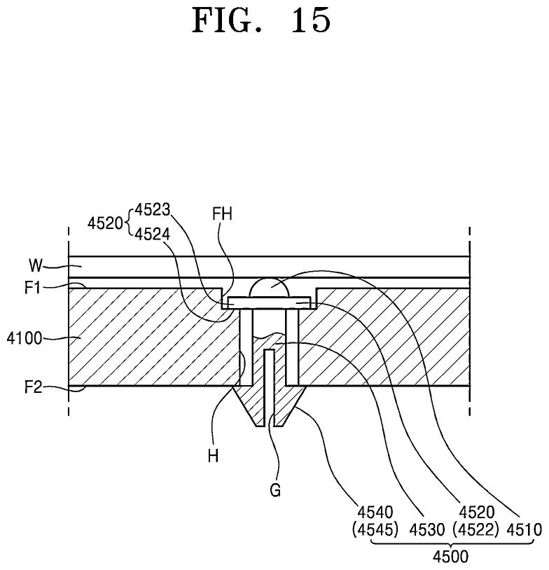

As shown in FIG. 15, in the through proximity pin 4500 according to some still further embodiments of the present disclosure, the second fixed portion 4540 may be embodied as an elastically-deformable portion 4545 formed in a general arrowhead shape and capable of elastic deformation so that the elastically-deformable portion 4545 is contracted when passing through the through-hole H and is expanded after exiting the through-hole.

In this regard, an elastic groove G may be formed in the elastically-deformable portion 4545 at a center thereof so as to bisect the elastically-deformable portion 4545, thereby increasing an amount of elastic deformation of the elastically-deformable portion 4545.

Therefore, while the operator does not need to separately assemble the above-mentioned C-ring CR or the fixing pin PN, the operator may simply pass the elastically-deformable portion 4545 through the through-hole H. Thus, the elastically-deformable portion 4545 is contracted when passing through the through-hole H and then is expanded after exiting the through-hole, such that the bottom of the through proximity pin 4500 may be easily fixed to the heating plate in one touch manner.

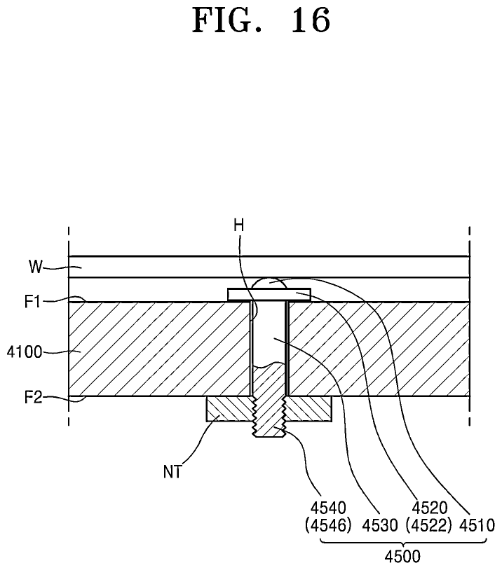

As shown in FIG. 16, in the through proximity pin 4500 according to some still further embodiments of the present disclosure, the second fixed portion 4540 may be embodied as a male threaded portion 4546 to which a fixing nut NT is screw-coupled.

Therefore, the operator may screw-couple the fixing nut NT to the male thread portion 4546 instead of using the above-described C-ring CR or the fixing pin PN to secure the lower portion of the through proximity pin 4500 to the heating plate.

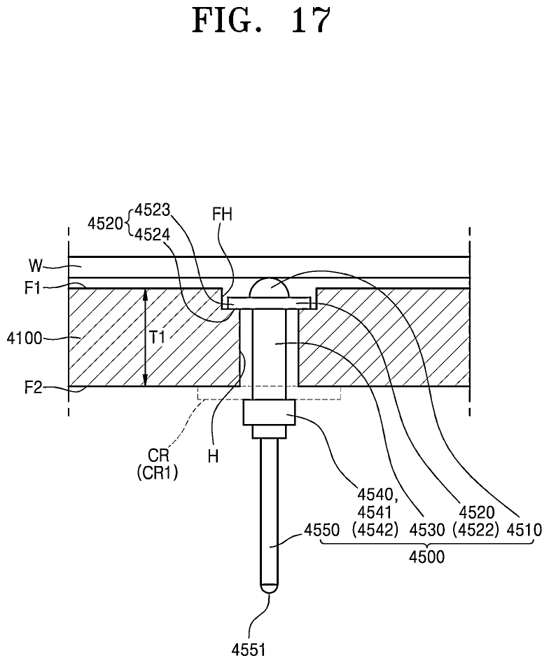

In one example, as shown in FIG. 17, the through proximity pin 4500 according to some still further embodiments of the present disclosure may further include a handle 4550 connected to the second fixed portion 4540 and gripped by a hand of the operator.

The handle 4550 may have a guide curved surface 4551 formed at a lower end thereof to smoothly guide the insertion when the through proximity pin 4500 passes through the through-hole H. This guide curved surface 4551 may have a rounded shape to alleviate impact in event of collision between parts. However, the guide curved surface 4551 may be formed in a variety of shapes, such as being formed in a form of an inclined surface.

Therefore, the operator has passed the handle 4550 through the through-hole H, and then holds the handle 4550 with one hand thereof to prevent the stepped portion 4542 from moving, and then holds the C-ring CR or the jigs J1, J2 for the C-ring with the other hand thereof and assembles the stepped portion 4542 and the C-ring CR with each other.

In this regard, although not shown, the handle 4550 may have a pre-formed cut. Thus, after the assembling, the handle may be cut at the pre-formed such that the handle may be (forcibly) removed from the stepped portion 4542.

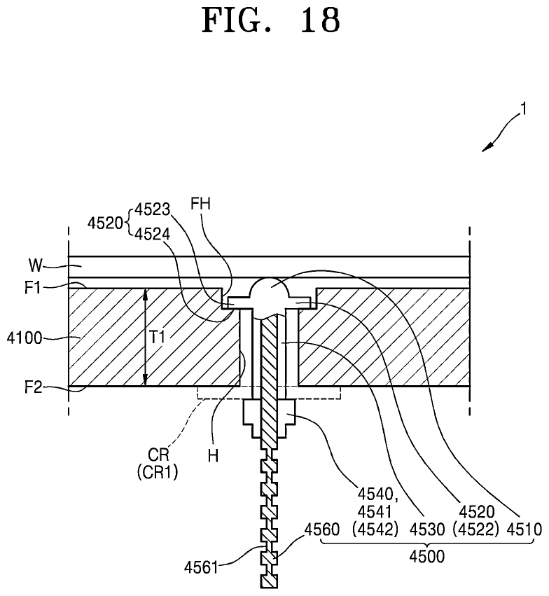

As shown in FIG. 18, the through proximity pin 4500 according to some still further embodiments of the present disclosure may further include a heat-dissipating portion 4560 connected to the second fixed portion 4540 and made of a heat dissipating material which is able to dissipate the heat transferred thereto from the head 4510 to the outside.

The heat-dissipating portion 4560 may be formed by double injection molding of a different material from a material of one selected from the head 4510, the first fixed portion 4520, the waist 4530, and the second fixed portion 4540 or a combination thereof, such that the heat-dissipating portion 4560 is disposed in the selected one.

A concave and convex surface 4561 may be formed on at least the portion of the heat-dissipating portion 4560 that may contact the outside air, thereby further improving heat dissipation.

Therefore, the thermal energy of the through proximity pin 4500 may be dissipated to the outside air through the heat-dissipating portion 4560 to prevent the phenomenon that the high temperature thermal energy generated from the heating plate 4100 flows through the through proximity pin 4500 and concentrates on the contact point thereof with the substrate W.

Therefore, according to various embodiments of the present disclosure as described above, the through proximity pin 4500 that may be conveniently installed into the ultra-thin heating plate 4100 may be used to overcome the limitation in reducing the thickness of the heating plate or the manufacturing limitation of the proximity pin. Convenience in assembly may be maximized using the C-ring, the fixing pin, the elastically-deformable portion, the fixing nut, the handle, etc. The through-hole H that extends vertically through the ultra-thin heating plate 4100 may be formed to eliminate the non-uniform stress concentration. The through proximity pin 4500 and the substrate W may come into point contact with each other and a contact area between the through proximity pin and the inner wall of the heat plate 4100 defining the through-hole H may be reduced to reduce thermal stress. Thermal shock to the substrate may be prevented by lowering the thermal conductivity of the head of the through proximity pin using an engineering plastic material such as PEEK or PEEK-CA with low thermal conductivity as the material of the head of the through proximity pin 4500. The substrate W may be heated quickly and uniformly by increasing heat dissipation using the through-hole H or the heat-dissipating portion 4560. A vertical level at which the substrate W is supported may be controlled by grinding the grinding target portion 4524.

In one example, the present disclosure provides the substrate processing apparatus 1 according to some further embodiments, which may include the housing 3232 having a treating space defined therein; and the support unit 1300 for supporting thereon the substrate W received in the treating space, wherein the support unit 1300 may include: the heating plate 4100 having a heating wire pattern built therein to heat the substrate; the lift pin 1340 installed in the heating plate so as to vertically move the substrate; the guide member 1350 for aligning the substrate at a correct position; the vacuum hole 1360 defined in the heating plate so as to generate a vacuum pressure so that the substrate is adsorbed to the heating plate; and the through proximity pin 4500 installed in the heating plate so as to pass through the through-hole H formed in the heating plate 4100 such that the substrate is spaced from the heating plate by a spacing via the through proximity pin.

In this regard, the housing 3232, the support unit 1300, the heating plate 4100, the lift pin 1340, the guide member 1350, and the through proximity pin 4500 installed in the heating plate so as to pass through the through-hole H formed in the heating plate 4100 such that the substrate is spaced from the heating plate by a spacing via the through proximity pin may respectively have the same configurations and roles as those of the components of the substrate processing apparatus 1 as described above. Therefore, detailed descriptions thereof are omitted.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A substrate processing apparatus comprising:
a heating plate for heating a substrate; and
a through proximity pin installed in the heating plate so as to pass through a through-hole formed in the heating plate such that the substrate is spaced from the heating plate by a spacing via the through proximity pin.

2. The substrate processing apparatus of claim 1, wherein the through proximity pin includes:
a head having a top, wherein a vertical level of the top is higher than a vertical level of an upper surface of the heating plate by the spacing so that the top is in contact with the substrate;
a first fixed portion connected to the head and having a diameter larger than a diameter of the through-hole so that the first fixed portion and the head connected thereto is supported on the heating plate; and
a waist connected to the first fixed portion and having a diameter smaller than or equal to the diameter of the through-hole such that the waist passes through the through-hole.

3. The substrate processing apparatus of claim 2, wherein the head has a spherical upper surface so as to be in point contact with the substrate.

4. The substrate processing apparatus of claim 2, wherein the first fixed portion is embodied as a flange contacting the upper surface of the heating plate.

5. The substrate processing apparatus of claim 2, wherein the first fixed portion is embodied as a flange inserted into a flange groove defined in the upper surface of the heating plate and extending from the through-hole.

6. The substrate processing apparatus of claim 5, wherein the flange includes:
a flange body protruding outwardly from and extending around the head in a ring shape; and
a grinding target portion including a lower surface of the flange body, wherein the grinding target portion is subjected to grinding so that the spacing can be selectively adjusted.

7. The substrate processing apparatus of claim 6, wherein the grinding target portion is embodied as a grinding target surface or at least one grinding target protrusion.

8. The substrate processing apparatus of claim 2, wherein the through proximity pin further includes a second fixed portion connected to the waist and fixed to the heating plate.

9. The substrate processing apparatus of claim 8, wherein the second fixed portion is embodied as a C-ring counterpart formed in a shape corresponding to a shape of a C-ring so that the waist is detachably fitted into the C-ring through an opening defined at one side thereof.

10. The substrate processing apparatus of claim 9, wherein the C-ring counterpart is embodied as a stepped portion having a diameter smaller than the diameter of the through-hole such that at least a portion thereof passes through the through-hole, and larger than the diameter of the waist such that the waist is fixed to the heating plate via the C-ring,
wherein the C-ring includes one selected from a planar C-ring, an inclined C-ring, and an elastic spring coupled C-ring.

11. The substrate processing apparatus of claim 9, wherein the C-ring counterpart is embodied as a C-ring groove formed in the waist and in a shape corresponding to the shape of the C-ring so that the waist is fixed to the heating plate via the C-ring.

12. The substrate processing apparatus of claim 8, wherein the second fixed portion includes a fixing pin counterpart formed in the waist and in a shape corresponding to a fixing pin so that the fixing pin is detachably inserted into the fixing pin counterpart,
wherein the fixing pin counterpart is embodied as a fixing pin receiving hole or groove.

13. The substrate processing apparatus of claim 8, wherein the second fixed portion is embodied as an elastically-deformable portion capable of elastic deformation so that the elastically-deformable portion is contracted when passing through the through-hole and is expanded after exiting the through-hole.

14. The substrate processing apparatus of claim 8, wherein the second fixed portion is embodied as a male threaded portion to which a fixing nut is screw-coupled.

15. The substrate processing apparatus of claim 8, wherein the through proximity pin further includes a handle connected to the second fixed portion, wherein the handle is gripped by a hand.

16. The substrate processing apparatus of claim 8, wherein the through proximity pin further includes a heat-dissipating portion connected to the second fixed portion and made of a heat dissipating material to dissipate heat transferred thereto from the head to an outside.

17. The substrate processing apparatus of claim 1, wherein the through proximity pin has a length larger than a thickness of the heating plate.

18. The substrate processing apparatus of claim 1, wherein the heating plate is embodied as an ultra-thin heating plate with a thickness of 2 mm or smaller, wherein the ultra-thin heating plate is used in a liquid film curing process of baking the substrate so as to dry a liquid film including a photo-resist film or an anti-reflection film applied onto the substrate, or in a substrate hydrophobization process of baking the substrate while supplying hexamethyldisilazane gas to increase adhesion of a photoresist.

19. A substrate processing apparatus comprising:
a housing having a treating space defined therein; and
a support unit for supporting thereon a substrate received in the treating space,
wherein the support unit includes:
a heating plate having a heating wire pattern built therein to heat the substrate;
a lift pin installed in the heating plate so as to vertically move the substrate;
a guide member for aligning the substrate at a correct position;
a vacuum hole defined in the heating plate so as to generate a vacuum pressure so that the substrate is adsorbed to the heating plate; and
a through proximity pin installed in the heating plate so as to pass through a through-hole formed in the heating plate such that the substrate is spaced from the heating plate by a spacing via the through proximity pin.

20. A substrate processing apparatus comprising:
a heating plate having a heating wire pattern built therein to heat a substrate; and
a through proximity pin installed in the heating plate so as to pass through a through-hole formed in the heating plate such that the substrate is spaced from the heating plate by a spacing via the through proximity pin,
wherein the through proximity pin includes:
a head having a top, wherein a vertical level of the top is higher than a vertical level of an upper surface of the heating plate by the spacing so that the top is in contact with the substrate;
a first fixed portion connected to the head and having a diameter larger than a diameter of the through-hole so that the first fixed portion and the head connected thereto is supported on the heating plate;
a waist connected to the first fixed portion and having a diameter smaller than or equal to the diameter of the through-hole such that the waist passes through the through-hole; and
a second fixed portion connected to the waist and fixed to the heating plate,
wherein the head has a spherical upper surface so as to be in point contact with the substrate,
wherein the first fixed portion is embodied as a flange inserted into a flange groove defined in an upper surface of the heating plate and extending from the through-hole,
wherein the flange includes:
a flange body protruding outwardly from and extending around the head in a ring shape; and
a grinding target portion including a lower surface of the flange body, wherein the grinding target portion is subjected to grinding so that the spacing can be selectively adjusted,
wherein the second fixed portion is embodied as a C-ring counterpart formed in a shape corresponding to a shape of a C-ring having an opening at one side thereof so that the C-ring counterpart is detachably fitted into the C-ring,
wherein the C-ring counterpart is embodied as a stepped portion having the diameter smaller than the diameter of the through-hole such that at least a portion thereof passes through the through-hole, and larger than the diameter of the waist such that the waist is fixed to the heating plate via the C-ring,
wherein the through proximity pin has a length larger than a thickness of the heating plate,
wherein the heating plate is embodied as an ultra-thin heating plate with a thickness of 2 mm or smaller, wherein the ultra-thin heating plate is used in a liquid film curing process of baking the substrate so as to dry a liquid film including a photo-resist film or an anti-reflection film applied onto the substrate.
